(19) United States
(12) Patent Application Publication
(10) Pub. No.: US 2010/0252864 A1
(43) Pub. Date: Oct. 7, 2010

(54) SEMICONDUCTOR DEVICE AND MANUFACTURING METHOD FOR THE SAME

(75) Inventor: Hisao KAWASAKI, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/716,622

(22) Filed: Mar. 3, 2010

(30) Foreign Application Priority Data
Apr. 7, 2009 (JP) 2009-093394

(51) Int. Cl. H01L 29/778; H01L 21/335

(52) U.S. Cl. 257/194; 438/285; 257/E29.246; 257/E21.403

(57) ABSTRACT

A semiconductor device which reduces source resistance and a manufacturing method for the same are provided. A semiconductor device has a nitride based compound semiconductor layer on a substrate and an active region on the nitride based compound semiconductor layer. The semiconductor device has a gate electrode, a source electrode and a drain on the active region, a source terminal electrode connected to the source electrode arranged on the nitride based compound semiconductor layer in a direction which the source electrode extends. Furthermore, the semiconductor device has an end face electrode which is arranged on the end face of the substrate in a source terminal electrode side, is connected to the source terminal electrode, and includes a multilayer metal layer including three or more layers which includes different metals, and prevents solder for die bonding from reaching the source terminal electrode.

### CROSS REFERENCE TO RELATED APPLICATION

This application is based upon and claims the benefit of priority from the prior Japanese Patent Application No. 2009-93394, filed on Apr. 7, 2009, the entire contents of which are incorporated herein by reference.

### FIELD OF THE INVENTION

The invention relates to a semiconductor device and a manufacturing method for the same, and relates especially to the semiconductor device which is capable of reducing a grounding inductance and operates in microwave band/millimeter wave band/submillimeter band, and the manufacturing method for the same.

### DESCRIPTION OF THE BACKGROUND

An FET (Field Effect Transistor) using compound semiconductors, such as GaN (Gallium Nitride), has outstanding high frequency characteristics and is widely put in practical use as a semiconductor device which operates in microwave band/millimeter wave band/submillimeter wave band.

A conventional semiconductor device is constituted as shown in FIGS. 11 and 12, for example. FIG. 11 shows a plane pattern structure diagram, and FIG. 12 shows a cross sectional view taken along a I-I line in FIG. 11. A semiconductor device has a substrate 10 formed of SiC, a GaN layer 12 arranged on the substrate 10, and gate electrode 24, source electrode 20 and drain electrode 22 which have a plurality of fingers respectively, arranged on the substrate 10. The semiconductor device has gate terminal electrodes GE1, GE2, GE3 which bundle a plurality of fingers of the gate electrode 24, source terminal electrode SE1, SE2, SE3, SE4 which bundle a plurality of fingers of the source electrode 20, and a drain terminal electrode DE which bundles a plurality of fingers of the drain electrode 22 arranged on the GaN layer 12,

A portion where the semiconductor device has the gate electrode 24, the source electrode 20 and the drain electrode 22 forms an active region AA which consists of an AlGaN layer 18 and a 2DEG (Two Dimensional Electron Gas) layer 16, as shown in FIG. 12. The 2DEG layer 16 is formed at the interface between the AlGaN layer 18 and the GaN layer 12. The source electrode 20 and the drain electrode 22 form an ohmic contact with the AlGaN layer 18 respectively, and the gate electrode 24 forms a schottky contact with the AlGaN layer 18.

Further, end face electrodes SC1, SC2, SC3, SC4 are formed to the source terminal electrodes SE1, SE2, SE3, SE4 respectively, and the end face electrode SC1, SC2, SC3, SC4 are connected to a ground conductor BE formed on the back of the substrate 10. The end face electrodes SC1, SC2, SC3, SC4 have an adhesion layer 30 which consists of Ti, and a metal layer 32 for grounding which consists of Au formed on the adhesion metal layer 30. The grounding inductance which has a bad influence on the high frequency characteristics of the semiconductor device can be reduced by forming the end face electrodes SC1, SC2, SC3, SC4 to the source electrode 20 and the source terminal electrodes SE1, SE2, SE3, SE4.

When grounding a circuit element provided on the substrate 10, the circuit element and the ground conductor BE are electrically connected via the end face electrode SC1, SC2, SC3, SC4.

In addition, the gate terminal electrodes GE1, GE2, GE3 are connected to a peripheral semiconductor chip by bonding wires etc., and the drain terminal electrode DE is also connected to a peripheral semiconductor chip by bonding wires etc.

JP,PH02-291133A discloses a semiconductor device in which a semiconductor chip has a side face metalized section and at least one side face among four side faces of the chip is not perpendicular to a chip surface.

However, solder to fix the semiconductor device to a package used in die bonding rises on the end face electrodes SC1, SC2, SC3, SC4. If the solder reaches the source terminal electrodes SE1, SE2, SE3, SE4 and the source electrode 20, the solder will react with the source terminal electrodes SE1, SE2, SE3, SE4 and the source electrode 20. For this reason, the semiconductor device having the end face electrode SC1, SC2, SC3, SC4 has a problem of causing increase of a source resistance.

### SUMMARY OF THE INVENTION

A purpose of the invention is to provide a semiconductor device for microwave band/millimeter wave band/submillimeter band which can prevent the increase in a source resistance and a manufacturing method for the same.

According to of the invention, a semiconductor device including a substrate; a nitride based compound semiconductor layer arranged on the substrate; an active region arranged on the nitride based compound semiconductor layer, and having an aluminum gallium nitride layer (AlₓGa₁₋ₓN) (0.1≦x≦1); a gate electrode arranged on the active region; a source electrode arranged on the active region; a drain electrode arranged on the active region; a gate terminal electrode arranged on the nitride based compound semiconductor layer in an extension direction of the gate electrode, and being connected to the gate electrode; a source terminal electrode arranged on the nitride based compound semiconductor layer in an extension direction of the source electrode, and being connected to the source electrode; a drain terminal electrode arranged on the nitride based compound semiconductor layer in an extension direction of the drain electrode, and being connected to the drain electrode; and an end face electrode arranged on an end face of the substrate in a source terminal electrode side, the end face electrode having at least three metal layers and each of the three metal layers consisting of different metal each other, is provided.

According to of the invention, a semiconductor device including a substrate; a nitride based compound semiconductor layer arranged on the substrate; an active region arranged on the nitride based compound semiconductor layer, and consisting of an aluminum gallium nitride layer (AlₓGa₁₋ₓN) (0.1≦x≦1); a gate electrode arranged on the active region and having a plurality of fingers; a source electrode arranged on the active region and having a plurality of fingers; a drain electrode arranged on the active region and having a plurality of fingers; a gate terminal electrode arranged on the nitride based compound semiconductor layer in an extension direction of the gate electrode, and bundling the plurality of fingers of the gate electrode; a source terminal electrode arranged on the nitride based compound semiconductor layer in an extension direction of the source electrode, and bundling the plurality of fingers of the source electrode; a drain terminal electrode arranged on the nitride based compound semiconductor layer in an extension direction of the drain electrode, and bundling the plurality of fingers of the drain electrode; an end face electrode arranged on an end face of the substrate in a source terminal electrode side, the end face electrode having at least three metal layers and each of the three metal layers consisting of different metal each other, is provided

According to of the invention, a method for manufacturing a semiconductor device including forming a nitride based compound semiconductor layer on a substrate; forming an active region including an aluminum gallium nitride layer (AlₓGa₁₋ₓN) (0.1≦x≦1) on the nitride based compound semiconductor layer; forming a gate electrode on the active region; forming a source electrode on the active region; forming a drain electrode on the active region; forming a gate terminal electrode connected to the gate electrode on the nitride based compound semiconductor layer in an extension direction of the gate electrode; forming a source terminal electrode connected to the source electrode on the nitride based compound semiconductor layer in an extension direction of the source electrode; forming a drain terminal electrode connected to the drain electrode on the nitride based compound semiconductor layer in an extension direction of the drain electrode; and forming an end face electrode arranged on an end face of the substrate in a source terminal electrode side, the end face electrode having at least three metal layers and each of the three metal layers consisting of different metal each other, is provided.

According to of the invention, a method for manufacturing a semiconductor device including forming a nitride based compound semiconductor layer arranged on a substrate; forming an active region including an aluminum gallium nitride layer (AlₓGa₁₋ₓN) (0.1≦x≦1) on the nitride based compound semiconductor layer; forming a gate electrode having a plurality of fingers on the active region; forming a source electrode having a plurality of fingers on the active region; forming a drain electrode having a plurality of fingers on the active region; forming a gate terminal electrode bundling the plurality of fingers of the gate electrode on the nitride based compound semiconductor layer in an extension direction of the gate electrode; forming a source terminal electrode bundling the plurality of fingers of the source electrode on the nitride based compound semiconductor layer in an extension direction of the source electrode; forming a drain terminal electrode bundling the plurality of fingers of the drain electrode on the nitride based compound semiconductor layer in an extension direction of the drain electrode; forming an end face electrode formed on an end face of the substrate in a source terminal electrode side, the end face electrode having at least three metal layers and each of the three metal layers consisting of different metal each other.

### BRIEF DESCRIPTION OF THE DRAWINGS

FIG. 1 is a plane view showing a schematic plane pattern structure of a semiconductor device concerning a first embodiment of the invention;

FIG. 2 is a sectional view showing a schematic cross sectional structure taken along a II-II line in FIG. 1;

FIG. 3 is a cross sectional view showing a schematic cross sectional structure of a constitutional example 1 of the semiconductor device concerning the first embodiment of the invention;

FIG. 4 is a cross sectional view showing a schematic cross sectional structure of a constitutional example 2 of the semiconductor device concerning the first embodiment of the invention;

FIG. 5 is a cross sectional view showing a schematic cross sectional structure of a constitutional example 3 of the semiconductor device concerning the first embodiment of the invention;

FIG. 6 is a cross sectional view showing a schematic cross sectional structure explaining another manufacturing method of the semiconductor device concerning the first embodiment of the invention;

FIG. 7 is a cross sectional view showing a schematic cross sectional structure explaining still another manufacturing method of the semiconductor device concerning the first embodiment of the invention;

FIG. 8 is a plane view showing a schematic plane pattern structure of a semiconductor device concerning a second embodiment of the invention;

FIG. 9 is a cross sectional view showing a schematic cross sectional structure taken along a IV-IV line in FIG. 8;

FIG. 10 is a cross sectional view showing a schematic cross sectional structure explaining another manufacturing method of the semiconductor device concerning the second embodiment of the invention;

FIG. 11 is a plane view showing a schematic plane pattern structure of a conventional semiconductor device; and

FIG. 12 is a cross sectional view showing a schematic cross sectional structure taken along a I-I line in FIG. 11;

### DETAILED DESCRIPTION OF THE INVENTION

Hereinafter, the embodiment of the invention will be explained with reference to accompanying drawings. In the following drawings, identical or similar numerals are given to the identical or similar portion.

### First Embodiment

(Device Structure)

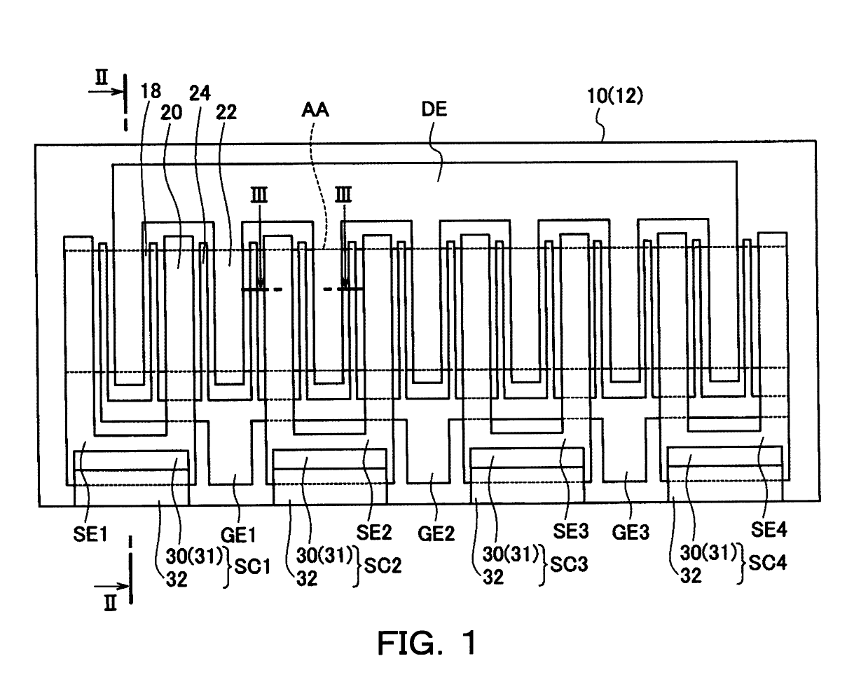

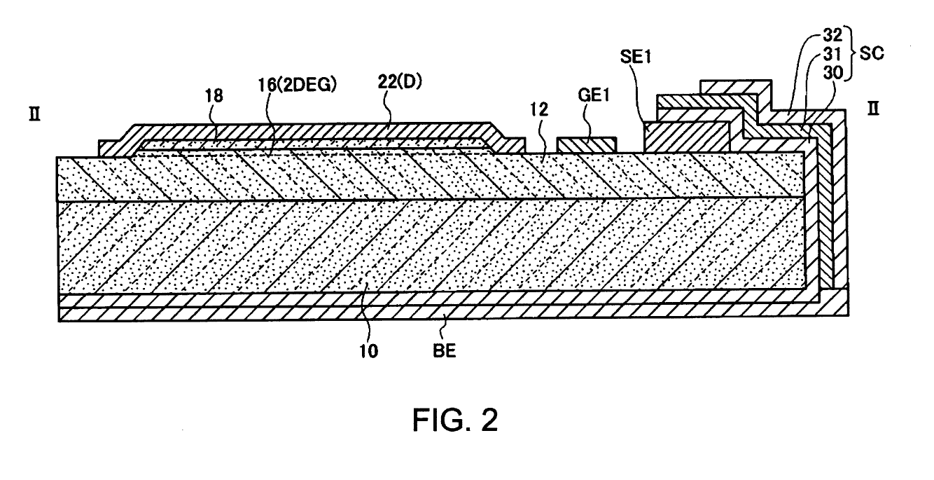

FIG. 1 shows a schematic plane pattern structure of a semiconductor device concerning the first embodiment of the invention. In addition, FIG. 2 shows a schematic cross sectional structure taken along a II-II line in FIG. 1.

As shown in FIGS. 1 and 2, the semiconductor device concerning the first embodiment has a substrate 10 which has SiC substrate, a nitride based compound semiconductor layer 12 arranged on the substrate 10, and an active region AA which has an aluminum gallium nitride layer (AlₓGa₁₋ₓN) (0.1≦x≦1) 18 arranged on the nitride based compound semiconductor layer 12. The semiconductor device has a gate electrode 24, a source electrode 20, and a drain electrode 22 arranged on the active region AA. Further, the semiconductor device has gate terminal electrodes GE1, GE2, GE3 connected to the gate electrode 24, source terminal electrodes SE1, SE2, SE3, SE4 connected to the source electrode 20 and a drain terminal electrode DE connected to the drain electrode 22 arranged on the nitride based compound semiconductor layer 12. Furthermore, the semiconductor device has end face electrodes SC1, SC2, SC3, SC4 which are connected to the source terminal electrodes SE1, SE2, SE3, SE4 respectively, and are arranged on an end face of the substrate 10 at source terminal electrodes side.

The gate electrode 24, the source electrode 20, and the drain electrode 22 have a plurality of fingers respectively. The gate terminal electrodes GE1, GE2, GE3, the source terminal electrodes SE1, SE1, SE2, SE3, SE4 and the drain terminal electrode DE are arranged on the nitride based compound semiconductor layer 12 in a direction which the gate electrode 24, the source electrode 20 and the drain electrode 22 extend. Further, the gate terminal electrodes GE1, GE2, GE3 bundle the plurality of fingers of the gate electrode 24, the source terminal electrodes SE1, SE2, SE3, SE4 bundle the plurality of fingers of the source electrode 20, and the drain terminal electrode DE bundles the plurality of fingers of the drain electrode 22.

The gate electrode 24 and the gate terminal electrodes GE1, GE2, GE3 are formed of Ni/Au, for example. And the source electrode 20, the drain electrode 22, the source terminal electrodes SE1, SE2, SE3, SE4 and the drain terminal electrode DE are formed of Ti/Al/Ti/PT/Au, for example.

The aluminum gallium nitride layer (AlₓGa₁₋ₓN) (0.1≦x≦1) 18 between the gate electrode 24 and the source electrodes 20, between the gate electrode 24 and the drain electrode 22, under the gate electrode 24, under the source electrode 20 and under the drain electrode 22 forms the active region AA.

A schottky contact is formed at an interface between the gate electrode 24 and the aluminum gallium nitride layer 18. An ohmic contact is formed between the source electrode 20 and the aluminum gallium nitride layer 18, and an ohmic contact is formed between the drain electrode 22 and the aluminum gallium nitride layer 18.

The end face electrodes SC1, SC2, SC3, SC4 are directly connected to the source terminal electrodes SE1, SE2, SE3, SE4 respectively. The end face electrodes SC1, SC2, SC3, SC4 have an adhesion layer 30 directly attached on an end face of the substrate 10, a barrier metal layer 31 arranged on the adhesion layer 30, and a metal layer 32 for grounding arranged on the barrier metal layers 31. The metal layer 32 for grounding is formed so that an edge of the metal layer 32 at active region AA side retreats to the end face side of the substrate rather than an edge of the barrier metal layer 31.

The end face electrodes SC1, SC2, SC3, SC4 which include the adhesion layer 30, the barrier metal layers 31, and the metal layer 32 for grounding are connected to a ground conductor BE formed on the back of the substrate 10 as shown in FIG. 2.

The adhesion layer 30 is formed of a Ti layer, for example, the barrier metal layer 31 is formed of a layer which contains any one of Pt, Pd, Mo, Ta, or W, for example, and the metal layer 32 for grounding is formed of an Au layer, for example.

The end face electrodes SC1, SC2, SC3, SC4 have at least three metal layers, and the three metal layers includes mutually different metals. The end face electrodes SC1, SC2, SC3, SC4 are not restricted to a three-layered structure and can increase the number of metal layers if needed.

The substrate 10 can be formed of a GaAs substrate, a GaN substrate, a substrate having a GaN epitaxial layer formed on a SiC substrate, a substrate having a GaN epitaxial layer formed on a Si substrate, a substrate having a hetero-junction epitaxial layer of GaN/AlGaN formed on a SiC substrate, a substrate having a GaN epitaxial layer formed on a sapphire substrate, a sapphire substrate or a diamond substrate other than the Sic substrate.

In addition, the nitride based compound semiconductor layer 12 other than the active region AA is used as an electrically inactivity device isolation region. However, the device isolation region can also be formed by implanting ions to the aluminum gallium nitride layer (AlₓGa₁₋ₓN)) (0.1≦x≦1) 18 and a part of depth direction of the nitride based compound semiconductor layer 12. As ionic species, nitrogen (N) or argon (Ar) is applicable, for example. Further, an amount of dose in the ion implantation is about 1×10¹⁴ (ions/cm²), for example, and accelerating energy is about 100 keV-200 keV, for example.

An insulating layer for passivation (illustration is omitted) is formed on the device isolation region and a semiconductor device surface. This insulating layer can be formed of a nitride film, an alumina (Al₂O₃) film, an oxide film (SiO₂), or an acid nitride (SiON) film, for example, deposited by the PECVD (Plasma Enhanced Chemical Vapor Deposition) method, for example.

As an operating frequency become high as microwave band/millimeter wave band/submillimeter wave band, a pattern length of a longitudinal direction of the gate electrode 24, source electrode 20 and drain electrode 22 is set short. The pattern length is about 25 micrometers-50 micrometers, for example, in millimeter wave band.

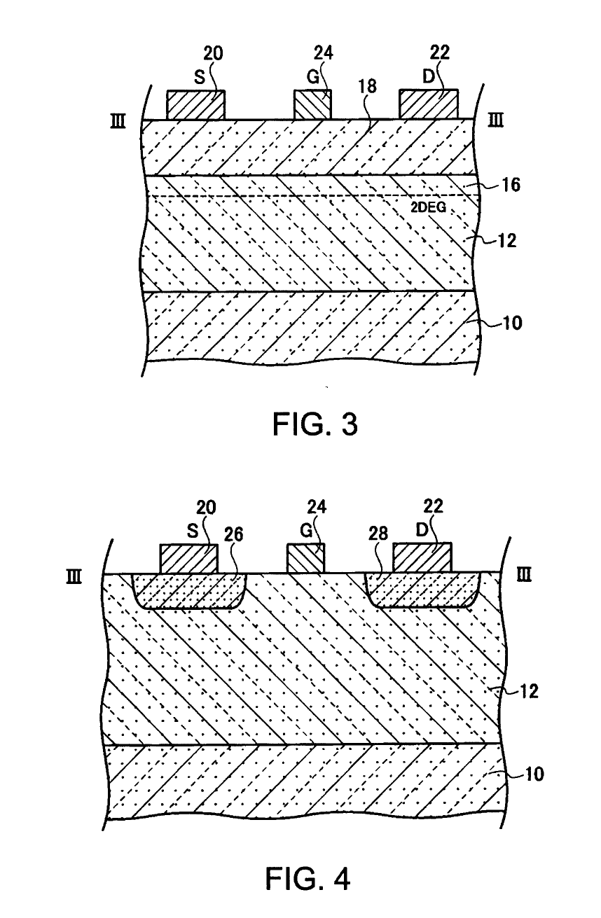

FIGS. 3-5 show schematic cross sectional structures taken along a III-III line in FIG. 1, and FIGS. 3-5 correspond to constitution examples 1-3 of the semiconductor device concerning the first embodiment respectively.

### Constitutional Example 1

As shown in FIG. 3, a semiconductor device has a substrate 10, a GaN epitaxial growth layer 12 arranged on the substrate 10, a aluminum gallium nitride layer (AlₓGa₁₋ₓN) (0.1≦x≦1) 18 arranged on the GaN epitaxial growth layer 12, and a source electrode 20, a gate electrode 24 and a drain electrode 22 which have been arranged on the aluminum gallium nitride layer (AlₓGa₁₋ₓN) (0.1≦x≦1) 18. A 2DEG layer 16 is formed in the interface between the GaN epitaxial growth layer 12 and the aluminum gallium nitride layer (AlₓGa₁₋ₓN) (0.1≦x≦1) 18. In the semiconductor device shown in FIG. 3, an HEMT (High Electron Mobility Transistor) is configured.

### Constitutional Example 2

Another constitutional example is shown in FIG. 4. A semiconductor device has a substrate 10, a GaN epitaxial growth layer 12 arranged on the substrate 10, a source region 26 and a drain area 28 formed in the GaN epitaxial growth layer 12, a source electrode 20 arranged on the source region 26, a gate electrode 24 arranged on the GaN epitaxial growth layer 12, and a drain electrode 22 arranged on the drain area 28.

In the semiconductor device shown in FIG. 4, an MESFET (Metal Semiconductor Field Effect Transistor) is configured.

### Constitutional Example 3

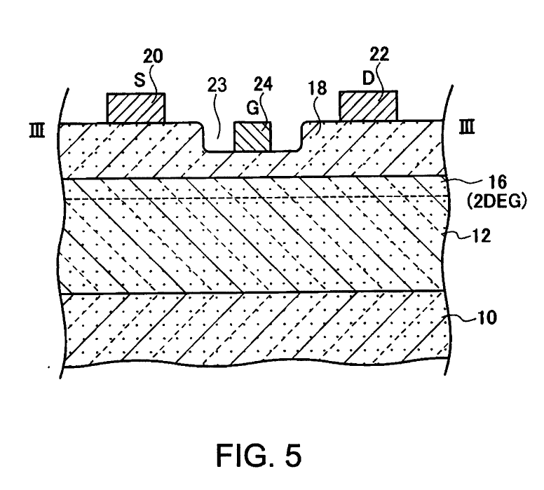

Still another constitutional example is shown in FIG. 5. A semiconductor device has a substrate 10, a GaN epitaxial growth layer 12 arranged on the substrate 10, a aluminum gallium nitride layer (AlₓGa₁₋ₓN) (0.1≦x≦1) 18 arranged on the GaN epitaxial growth layer 12, a source electrode 20 and a drain electrode 22 arranged on the aluminum gallium nitride layer (AlₓGa₁₋ₓN) (0.1≦x≦1) 18, and a gate electrode 24 arranged on a recessed portion 23 of the aluminum gallium nitride layer (AlₓGa₁₋ₓN) (0.1≦x≦1) 18. The 2DEG layer 16 is formed at the interface between the GaN epitaxial growth layer 12 and the aluminum gallium nitride layer (AlₓGa₁₋ₓN) (0.1≦x≦1) 18. The semiconductor device shown in FIG. 5 corresponds to the HEMT which has a recess gate structure.

### Manufacturing Method

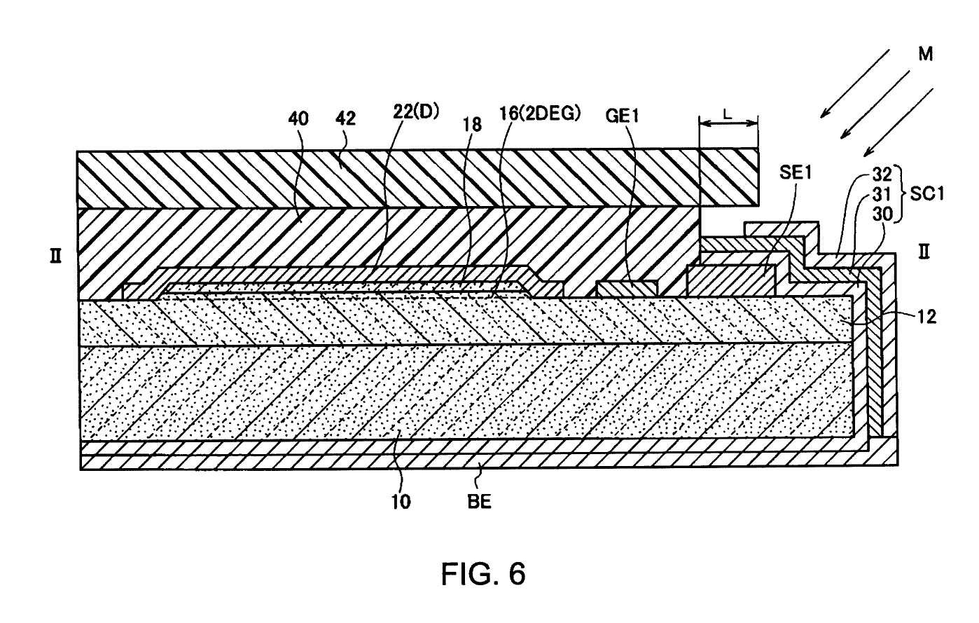

Hereinafter, with reference to FIG. 6, an example of the manufacturing method of the semiconductor device concerning the first embodiment of the invention is explained in detail.

(a) TMG (trimethyl gallium) and ammonia gas are passed on the SiC substrate 10 to form the GaN epitaxial growth layer 12 which is the nitride based compound semiconductor layer of a thickness of about 1 micrometer, for example, by epitaxial growth method.

(b) Next, TMAl (trimethyl aluminum) and ammonia gas are passed to form the aluminum gallium nitride layer (AlₓGa₁₋ₓN) (0.1≦x≦1) 18 of about 30% of Al composition ratio, for example, and of a thickness of about 20 nm-100 nm, for example, on the GaN epitaxial growth layer 12 by the epitaxial growth method. Thereby, the 2DEG16 is formed. Further, unnecessary portions of the aluminum gallium nitride layer 18 and the GaN epitaxial growth layer 12 are removed by a well-known etching method so that the region used as the active region AA may remain.

(c) Next, Ti/Al/Ti/Pt/Au are vapor-deposited in order on the GaN epitaxial growth layer 12 and the aluminum gallium nitride layer 18. This metal laminated film is etched by a well-known etching method so that the source electrode 20 and the drain electrode 22 which have a plurality of fingers respectively, may be formed on the active region AA. The source terminal electrodes SE1-SE4 which are connected to the source electrode 20 and bundle a plurality of fingers of the source electrode 20 and the drain terminal electrode DE which is connected to the drain electrode 22 and bundles a plurality of fingers of the drain electrode 22, are formed on the GaN epitaxial growth layer 12 in the direction which the source electrode 20 and the drain electrode 22 extend in this etching. The source electrode 20 and the aluminum gallium nitride layer 18 form the ohmic contact, and the drain electrode 22 and the aluminum gallium nitride layer 18 form the ohmic contact.

(d) Next, Ni/Au are vapor-deposited on the GaN epitaxial growth layer 12 and the aluminum gallium nitride layer 18 on which the source electrode 20, the drain electrode 22, the source terminal electrodes SE1-SE4 and the drain terminal electrode DE are formed. This metal laminated layer is etched by a well-known etching method to form the gate electrode 24 which has the plurality of fingers and the gate terminal electrodes GE1, GE2, GE3, GE4 which bundle the plurality of the fingers and are connected to the gate electrode on the GaN epitaxial growth layer 12 in the direction which the gate electrode 24 extends. The gate electrode 24 and the aluminum gallium nitride layer 18 form the schottky contact.

(e) Next, the substrate 10 is polished from the back to thin the substrate 10 using a CMP (Chemical Mechanical Polishing) technique. Here, a thickness of the thinned substrate 10 is about 50 micrometers-100 micrometers, for example.

(f) Next, in order to form the adhesion layer which is directly connected to the source terminal electrodes SE1, SE2, SE3, SE4 and is directly formed on the end face of the substrate 10, the Ti layer 30 is formed on the entire surface of the semiconductor device, for example. The Ti layer may be formed on the back of the substrate 10 as shown in FIG. 6.

(g) Next, the ground conductor BE is formed on the back of the substrate 10 using the vacuum deposition technique etc.

(h) Next, in order to form the barrier metal layer, the Pt layer, for example, is formed on the Ti layer 30. A metal for forming the barrier metal layer is not restricted to Pt and a metal containing any one of Pt, Pd, Mo, Ta, or W can be used for the metal for forming the barrier metal layer.

(i) Next, by the etching method of well-known which uses a photoresist layer, as shown in FIG. 1, the Ti layer 30 and the Pt layer 31 are patterned so that the Ti layer 30 and the Pt layer 31 may overlap with partial regions of the source terminal electrodes SE1, SE2, SE3, SE4. Thereby, the adhesion layer 30 and the barrier metal layer 31 are formed.

(j) Next, a photoresist layer 40 is applied on the entire surface of the semiconductor device, and the photoresist layer 40 is patterned in the shape of the adhesion layer 30 and the barrier metal layers 31. Further, a photoresist layer 42 is applied on a surface of the semiconductor device on which the photoresist layer 40 is formed. The photoresist layer 42 is patterned so that the photoresist layer 42 may become the shape of the adhesion layer 30 and the barrier metal layers 31 and the photoresist layer 42 may overhang only distance L to the photoresist layer 40.

(k) Next, in order to form the metal layer for grounding, the Au layer 32 is formed on the barrier layer 31 using an oblique vapor-depositing method via the photoresist layers 42, 40 which were patterned thus.

When removing the photoresist layer 40, the photoresist layer 42 and the Au layer on the photoresist layer 42, the metal layer 32 for grounding of Au formed on the barrier layer 31 is obtained. On the source terminal electrode SE1, SE2, SE3, SE4, the edge of the metal layer 32 for grounding retreats rather than the edge of the barrier metal layers 31. Thus, the end face electrodes SC1, SC2, SC3, SC4 are formed.

The semiconductor device concerning the first embodiment shown in FIGS. 1, 2 is obtained by the above (a)-(k) steps.

In the above-mentioned explanation, the photoresist layer is formed in two-layer in order to form the overhang of the photoresist layer. However, the photoresist layer may be formed in a multilayer of three or more layers. The end face electrodes SC1, SC2, SC3, SC4 have a multilevel metal layer which includes at least three or more layers and each layer is formed of different metal from other layers. The end face electrodes SC1, SC2, SC3, SC4 can includes more that four layers at necessity.

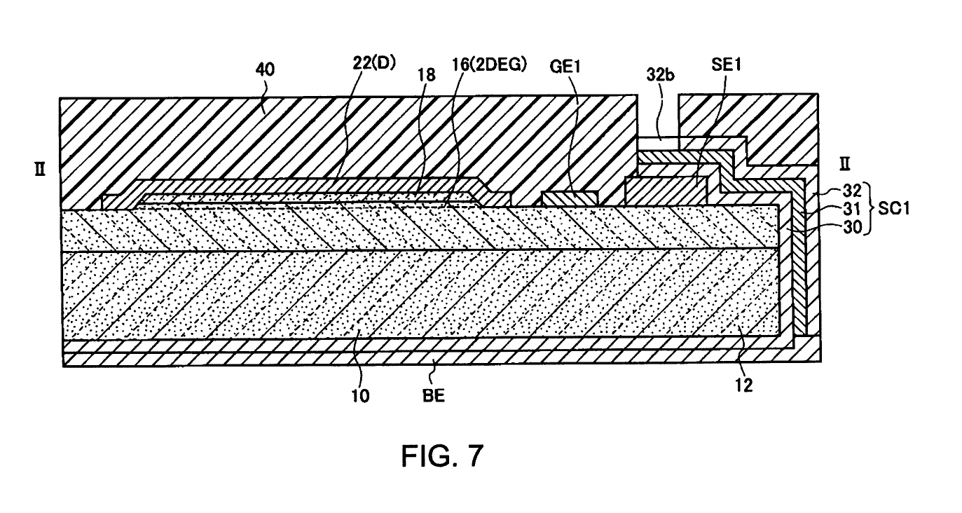

The end face electrodes SC1, SC2, SC3, SC4 can be manufactured by a method other than the method described above. As shown in FIG. 7, the Ti layer 30 is formed on the device entire surface, the predetermined end face of the substrate 10 and the back of the substrate 10. Next, the grounding electrode BE is formed on the back of the substrate 10. Next, the Pt layer 31 and the Au layer 32 are formed on the device entire surface and the predetermined end face of the substrate 10.

Next, a photoresist layer is applied on a device entire surface, and the photoresist layer is patterned in the shape of the end face electrodes SC1, SC2, SSC3, SC4 to be formed. Unnecessary regions of the Ti layer 30, the Pt layer 31 and the Au layer 32 are etched by using the patterned photoresist layer as a mask, and the adhesion layer 30, the barrier metal layers 31 and the Au layer 32 are formed. And the photoresist layer is removed.

Further, the photoresist layer 40 is applied on the device entire surface. In order to remove a part of the metal layer 32 for grounding in an active region AA side, the photoresist layer 40 is patterned by removing the photoresist layer 40 of the region corresponding to an etched region 32b of a metal layer 32 for grounding. The etched region 32b of the Au layer 32 is removed by etching using the patterned photoresist layer 40 as a mask. Thereby, the metal layer 32 for grounding in which the edge of the metal layer 32 for grounding in the active region AA side retreats to the end face side of the substrate 10 rather than the edge of the barrier metal layer 31 is formed. And the photoresist layer 40 is removed and the end face electrodes SC1, SC2, SC3, SC4 are formed.

According to the semiconductor device concerning the invention and the semiconductor device by the manufacturing method of the invention, the end face electrodes SC1, SC2, SC3, SC4 have at least three metal layers, and three metal layers are formed from mutually different metals. By this, solder (illustration is omitted) used in die bonding which fixes the semiconductor device to a package can be prevented from reaching the source terminal electrodes SE1, SE2, SC3, SE4 and the source electrode 20, and the increase in the source resistance can be prevented. That is, a reaction between AuSn, for example, contained in the solder and the Au layer, for example, constitutes the source terminal electrodes SE1, SE2, SE3, SE4 and the source electrode 20, can be inhibited, and thereby the increase in the source resistance can be prevented.

According to the semiconductor device of the invention and the semiconductor device manufactured by the manufacturing method of the invention, the semiconductor device has the barrier metal layer 31 in the multilevel metal layer which constitutes the end face electrodes SC1, SC2, SC3, SC4. Even if the solder includes an ingredient that reacts with the source electrode material, the barrier metal layer 31 prevents the ingredient of the solder from diffusing in the source electrode. By this, the semiconductor device can prevent the increase of the source resistance.

In addition, according to the semiconductor device by the first embodiment of the invention and the semiconductor device by the manufacturing method of the invention, the metal layer 32 for grounding of the end face electrodes SC1, SC2, SC3, SC4 is formed so that the edges of the end face electrodes SC1, SC2, SC3, SC4 in the active region AA side may retreat to the end face side of the substrate 10 rather than the edge of the barrier metal layer 31. By this, the solder (illustration is omitted) used in die bonding which fixes the semiconductor device to a package can be prevented from reaching the source terminal electrodes SE1, SE2, SE3, SE4 and the source electrode 20, and thereby the increase in source resistance can be prevented.

### Second Embodiment

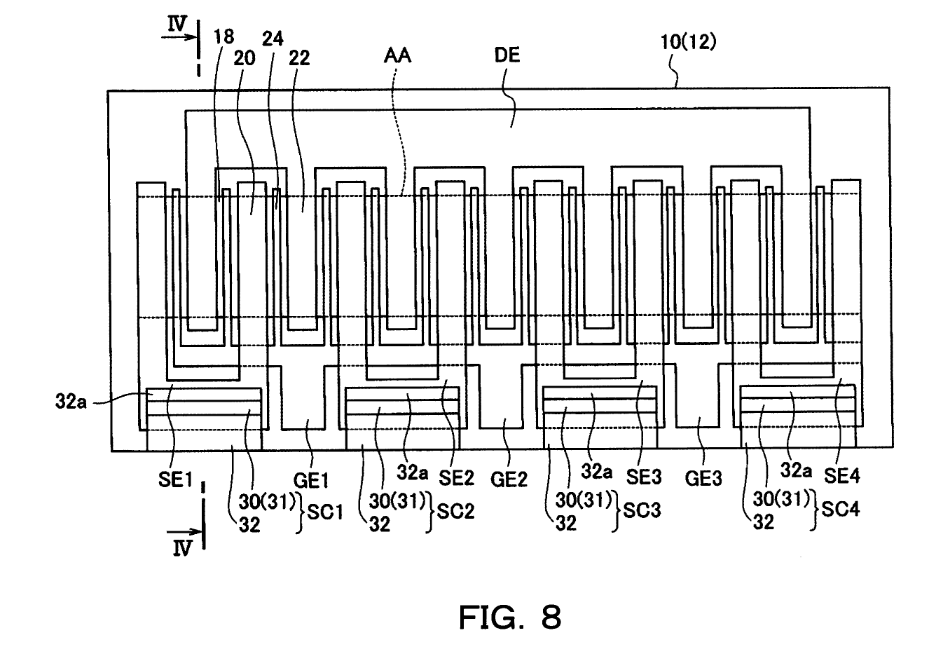

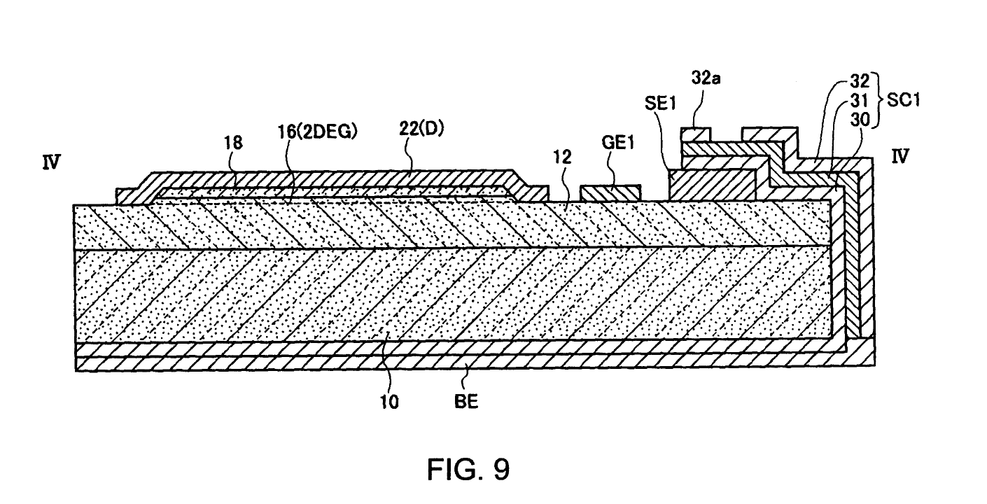

FIG. 8 shows a schematic plane pattern structure of a semiconductor device concerning the second embodiment. FIG. 9 shows a schematic cross sectional structure taken along a IV-IV line in FIG. 8.

The semiconductor device concerning the second embodiment differs from the first embodiment in that a part of a metal layer 32 for grounding is removed in a slit shape. Other structures are the same as that of the first embodiment, so that the overlapping explanation is omitted. End face electrodes SC1, SC2, SC3, SC4 include an adhesion layer 30 directly formed on source terminal electrodes SE1, SE2, SE3, SE4 and an end face of a substrate 10, a barrier metal layer 31 arranged on the adhesion layer 30, and the metal layers 32 and 32a for grounding arranged on the barrier metal layer 31.

A manufacturing method of the semiconductor device of the second embodiment differs from the first embodiment in a step of forming the end face electrodes SC1, SC2, SC3, SC4. Other manufacturing steps are the same as that of the first embodiment, so that the overlapping explanation is omitted.

A step of forming the end face electrodes SC1, SC2, SC3, SC4 is performed as follows. Like the other manufacturing method of the semiconductor device concerning the first embodiment, a Ti layer 30 is formed on the entire surface of the semiconductor device as the adhesion layer which is formed directly on the source terminal electrodes SE1, SE2, SE3, SE4 and the end face of the substrate 10, a Pt layer 31 is formed on the Ti layer 30 as the barrier metal layer, and an Au layer 32 is also formed on the Pt layer 31 as the metal layer for grounding. Then, by etching which uses a photoresist layer, the unnecessary regions of the Ti layer 30, the Pt layer 31 and the Au layer 32 are removed, and thereby these metal layers are etched into the shape of the end face electrodes SC1, SC2, SC3, SC4. And then, the photoresist layer is removed. Thereby, the adhesion layer 30, the barrier metal layer 31 and the patterned Au layer 32 are formed.

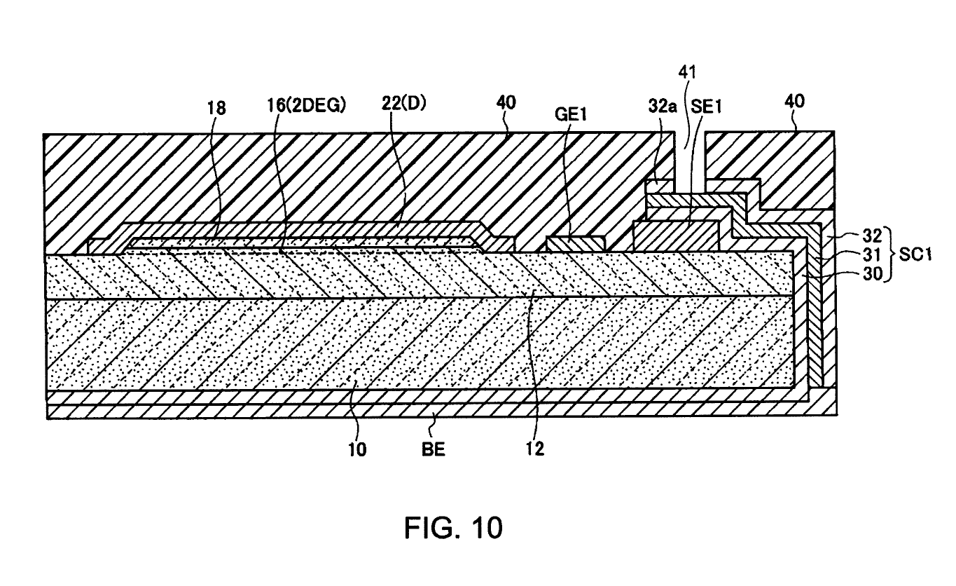

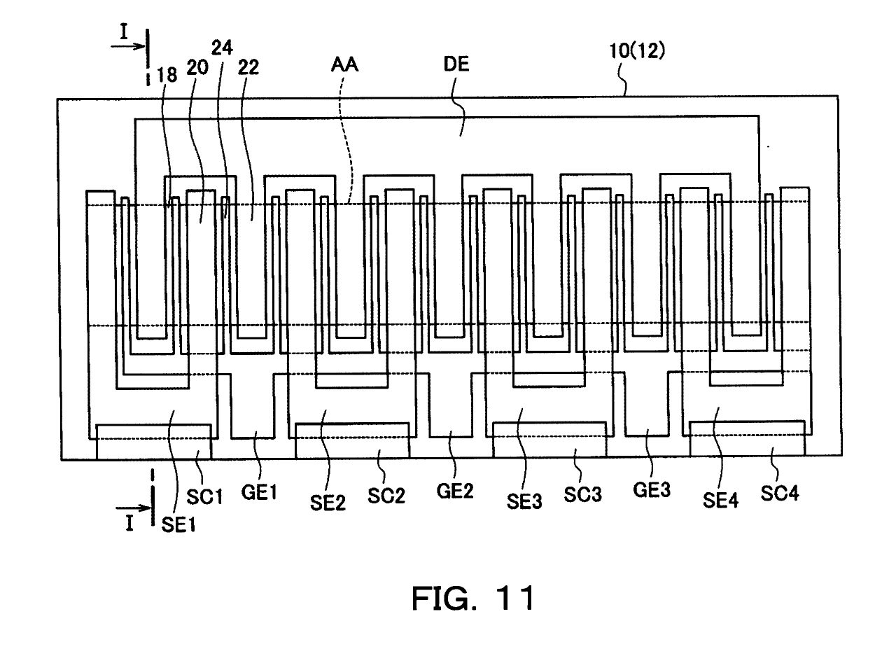

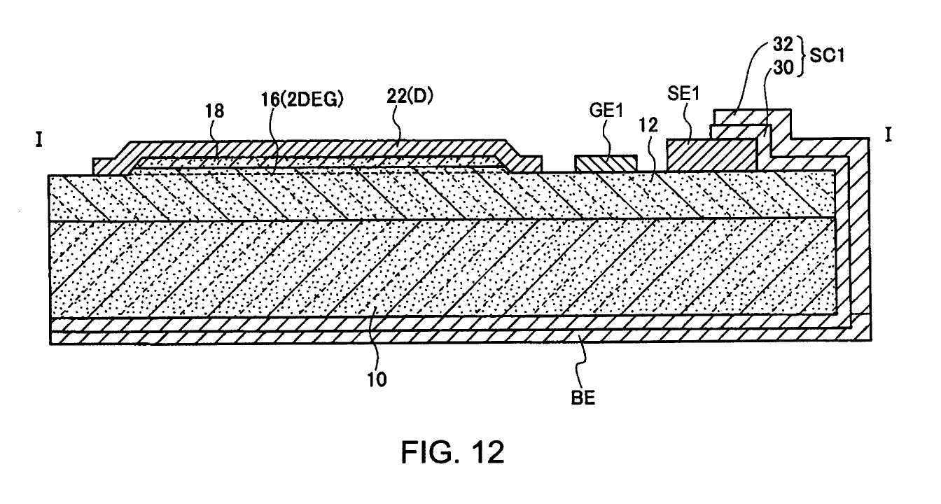

Next, as shown in FIG. 10, a photoresist layer 40 is applied on the entire surface of the semiconductor device, and a groove 41 for removing a part of the Au layer 32 in the slit shape is formed in the photoresist layer 40. Only the Au layer 32 of the portion corresponding to the groove 41 is etched by using the photoresist layer 40 as a mask to remove the part of the Au layer 32 in the slit shape. Thereby, the metal layers 32 and 32a for grounding from which the part was removed in the slit shape are formed.

According to the semiconductor device by the second embodiment and the semiconductor device by the manufacturing method of the second embodiment, the end face electrodes SC1, SC2, SC3, SC4 have at least three metal layers, and three metal layers are formed from a mutually different metal. By this, solder (illustration is omitted) used in die bonding which fixes the semiconductor device to a package can be prevented from reaching the source terminal electrodes SE1, SE2, SE3, SE4 and the source electrode 20, and thereby the increase in source resistance can be prevented.

Further, according to the semiconductor device concerning the second embodiment, the solder used in the die bonding can be prevented from reaching the source terminal electrode and the source electrode by the barrier metal layer exposed in slit form from the metal layer for grounding. As a result, the semiconductor device for microwave band/millimeter wave band/submillimeter wave band device which can prevent the increase in source resistance and the manufacturing method for the same can be provided.

In the first and second embodiments, the end face electrodes SC1, SC2, SC3, SC4 are arranged at one side of the substrate 10 in the direction which the gate electrode 24, the source electrode 20 and the drain electrode 22 which have the plurality of fingers extend. However, the end face electrodes SC1, SC2, SC3, SC4 may be arranged not only at one side but at two sides which face each other. The end face electrodes SC1, SC2, SC3, SC4 may be arranged at one side of the substrate 10 in a direction which intersects perpendicularly with the extension direction of the gate electrode 24, the source electrode 20 and the drain electrode 22 having the plurality of fingers, or at two sides which face each other.

In the first and second embodiments, only one active region AA on which the gate electrode 24, the source electrode 20 and the drain electrode 22 having the plurality of fingers are arranged is arranged. However, a plurality of the active regions AA may be arranged on the substrate 10 in two or more lines or matrix form.

In addition, it is obvious that the semiconductor device of the invention is applied to not only the FET and the MESFET, but amplifying devices, such as an LDMOS (Lateral Doped Metal-Oxide-Semiconductor Field Effect Transistor) and an HBT (Hetero-junction Bipolar Transistor), and an MEMS (Micro Electro Mechanical Systems) element etc.

The semiconductor device of the invention is applicable to a broad field, such as an internal matching type power amplifying element, a power MMIC (Monolithic Microwave Integrated Circuit), a microwave power amplifier, a millimeter wave power amplifier, a high frequency MEMS element, etc.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a substrate;
a nitride based compound semiconductor layer arranged on the substrate;
an active region arranged on the nitride based compound semiconductor layer, and having an aluminum gallium nitride layer (AlₓGa₁₋ₓN) (0.1≦x≦1);
a gate electrode arranged on the active region;
a source electrode arranged on the active region;
a drain electrode arranged on the active region;
a gate terminal electrode arranged on the nitride based compound semiconductor layer in an extension direction of the gate electrode, and being connected to the gate electrode;
a source terminal electrode arranged on the nitride based compound semiconductor layer in an extension direction of the source electrode, and being connected to the source electrode;
a drain terminal electrode arranged on the nitride based compound semiconductor layer in an extension direction of the drain electrode, and being connected to the drain electrode; and
an end face electrode arranged on an end face of the substrate in a source terminal electrode side, the end face electrode having at least three metal layers and each of the three metal layers consisting of different metal each other.

2. A semiconductor device, comprising:
a substrate;
a nitride based compound semiconductor layer arranged on the substrate;
an active region arranged on the nitride based compound semiconductor layer, and consisting of an aluminum gallium nitride layer (AlₓGa₁₋ₓN) (0.1≦x≦1);
a gate electrode arranged on the active region and having a plurality of fingers;
a source electrode arranged on the active region and having a plurality of fingers;
a drain electrode arranged on the active region and having a plurality of fingers;
a gate terminal electrode arranged on the nitride based compound semiconductor layer in an extension direction of the gate electrode, and bundling the plurality of fingers of the gate electrode;
a source terminal electrode arranged on the nitride based compound semiconductor layer in an extension direction of the source electrode, and bundling the plurality of fingers of the source electrode;
a drain terminal electrode arranged on the nitride based compound semiconductor layer in an extension direction of the drain electrode, and bundling the plurality of fingers of the drain electrode;
an end face electrode arranged on an end face of the substrate in a source terminal electrode side, the end face electrode having at least three metal layers and each of the three metal layers consisting of different metal each other.

3. The semiconductor device according to claim 1 or claim 2, wherein the end face electrode includes an adhesion layer which is directly connected to the source terminal electrode and is adhered to the end face of the substrate, a barrier metal layer arranged on the adhesion layer, and a metal layer for grounding arranged on the barrier metal layer, and an edge of the metal layer for grounding retreats from an edge of the barrier metal layers.

4. The semiconductor device according to claim 1 or claim 2, wherein the end face electrode includes an adhesion layer which is directly connected to the source terminal electrode and is adhered to the end face of the substrate, a barrier metal layer arranged on the adhesion layer and a metal layer for grounding arranged on the barrier metal layer, and a part of the metal layer for grounding is removed in slit shape.

5. The semiconductor device according to claim 3, wherein the adhesion layer consists of a Ti layer, the barrier metal layers consists of a layer containing any one of Pt, Pd, Mo, Ta, or W, and the metal layer for grounding consists of Au layer.

6. The semiconductor device according to claim 4, wherein the adhesion layer consists of a Ti layer, the barrier metal layer consist of a layer containing any one of Pt, Pd, Mo, Ta, or W, and the metal layer for grounding consists of Au layer.

7. The semiconductor device according to claim 1 or claim 2, wherein the substrate includes any one of a SiC substrate, a GaAs substrate, a GaN board, a substrate having a GaN epitaxial layer formed on a SiC substrate, a substrate having a GaN epitaxial layer formed on a Si substrate, a substrate having a hetero-junction epitaxial layer which consists of GaN/AlGaN formed on a SiC substrate, a substrate having a GaN epitaxial layer formed on a sapphire substrate, a sapphire substrate, and a diamond substrate.

8. A method for manufacturing a semiconductor device, comprising:
forming a nitride based compound semiconductor layer on a substrate;
forming an active region including an aluminum gallium nitride layer (AlₓGa₁₋ₓN) (0.1≦x≦1) on the nitride based compound semiconductor layer;
forming a gate electrode on the active region;
forming a source electrode on the active region;
forming a drain electrode on the active region;
forming a gate terminal electrode connected to the gate electrode on the nitride based compound semiconductor layer in an extension direction of the gate electrode;
forming a source terminal electrode connected to the source electrode on the nitride based compound semiconductor layer in an extension direction of the source electrode;
forming a drain terminal electrode connected to the drain electrode on the nitride based compound semiconductor layer in an extension direction of the drain electrode; and
forming an end face electrode arranged on an end face of the substrate in a source terminal electrode side, the end face electrode having at least three metal layers and each of the three metal layers consisting of different metal each other.

9. A method for manufacturing a semiconductor device, comprising:
forming a nitride based compound semiconductor layer arranged on a substrate;
forming an active region including an aluminum gallium nitride layer (AlₓGa₁₋ₓN) (0.1≦x≦1) on the nitride based compound semiconductor layer;
forming a gate electrode having a plurality of fingers on the active region;
forming a source electrode having a plurality of fingers on the active region;
forming a drain electrode having a plurality of fingers on the active region;
forming a gate terminal electrode bundling the plurality of fingers of the gate electrode on the nitride based compound semiconductor layer in an extension direction of the gate electrode;
forming a source terminal electrode bundling the plurality of fingers of the source electrode on the nitride based compound semiconductor layer in an extension direction of the source electrode;
forming a drain terminal electrode bundling the plurality of fingers of the drain electrode on the nitride based compound semiconductor layer in an extension direction of the drain electrode;
forming an end face electrode formed on an end face of the substrate in a source terminal electrode side, the end face electrode having at least three metal layers and each of the three metal layers consisting of different metal each other.

10. The method for manufacturing a semiconductor device according to claim 8 or claim 9, wherein the step of forming the end face electrode includes forming an adhesion layer which is directly connected to the source terminal electrode and is laminated on the side of the substrate, forming a barrier metal layer on the adhesion layer, and forming a metal layer for grounding on the barrier metal layer so that an edge of the metal layer may retreat from an edge of the barrier metal layer.

11. The method for manufacturing a semiconductor device according to claim 8 or claim 9, wherein
the step of forming the end face electrode includes forming an adhesion layer which is directly connected to the source terminal electrode and is laminated on the side of the substrate, forming a barrier metal layer on the adhesion layer, forming a metal layer for grounding on the barrier metal layer, and
removing a part of the metal layer for grounding in slit shape.

12. The method for manufacturing a semiconductor device according to claim 10, wherein the adhesion layer consists of a Ti layer, the barrier metal layers consist of a layer containing any one of Pt, Pd, Mo, Ta, or W and the metal layer for grounding consists of Au layer.

13. The method for manufacturing a semiconductor device according to claim 11, wherein the adhesion layer consists of a Ti layer, the barrier metal layers consist of a layer containing any one of Pt, Pd, Mo, Ta, or W and the metal layer for grounding consists of Au layer.

14. The method for manufacturing a semiconductor device according to claim 8 or claim 9, wherein the substrate is any one of a SiC substrate, a GaAs substrate, a GaN substrate, a substrate having a GaN epitaxial layer formed on a SiC substrate, a substrate having a GaN epitaxial layer formed on a Si substrate, a substrate having a hetero-junction epitaxial layer of GaN/AlGaN formed on a SiC substrate, a substrate having a GaN epitaxial layer formed on a sapphire substrate, a sapphire substrate or a diamond substrate.

15. The method for manufacturing a semiconductor device according to claim 10, wherein the metal layer of grounding is formed by an oblique vapor deposition method.

16. A semiconductor device, comprising:
a substrate;
a nitride based compound semiconductor layer arranged on the substrate;
an active region arranged on the nitride based compound semiconductor layer, and consisting of an aluminum gallium nitride layer (AlₓGa₁₋ₓN) (0.1≦x≦1);
a gate electrode arranged on the active region and having a plurality of fingers;
a source electrode arranged on the active region and having a plurality of fingers;
a drain electrode arranged on the active region and having a plurality of fingers;
a gate terminal electrode arranged on the nitride based compound semiconductor layer in an extension direction of the gate electrode, and bundling the plurality of fingers of the gate electrode;
a source terminal electrode arranged on the nitride based compound semiconductor layer in an extension direction of the source electrode, and bundling the plurality of fingers of the source electrode;
a drain terminal electrode arranged on the nitride based compound semiconductor layer in an extension direction of the drain electrode, and bundling the plurality of fingers of the drain electrode; and
an end face electrode including
an adhesion layer arranged on an end face of the substrate in a source terminal electrode side, being directly connected to the source terminal electrode and being attached on the end face of the substrate;
a barrier metal layer arranged on the adhesion layer; and
a metal layer for grounding arranged on the barrier metal layer, the edge of the metal layer for grounding being retreating from an edge of the barrier metal layer.

17. A semiconductor device, comprising:
a substrate;
a nitride based compound semiconductor layer arranged on the substrate;
an active region arranged on the nitride based compound semiconductor layer, and consisting of an aluminum gallium nitride layer (AlₓGa₁₋ₓN) (0.1≦x≦1);
a gate electrode arranged on the active region and having a plurality of fingers;
a source electrode arranged on the active region and having a plurality of fingers;
a drain electrode arranged on the active region and having a plurality of fingers;
a gate terminal electrode arranged on the nitride based compound semiconductor layer in an extension direction of the gate electrode, and bundling the plurality of fingers of the gate electrode;
a source terminal electrode arranged on the nitride based compound semiconductor layer in an extension direction of the source electrode, and bundling the plurality of fingers of the source electrode;
a drain terminal electrode arranged on the nitride based compound semiconductor layer in an extension direction of the drain electrode, and bundling the plurality of fingers of the drain electrode; and
an end face electrode including
an adhesion layer arranged on an end face of the substrate in a source terminal electrode side, being directly connected to the source terminal electrode and being attached on the said of the substrate;
a barrier metal layer arranged on the adhesion layer; and
a metal layer for grounding arranged on the barrier metal layer, and a part of the metal layer for grounding being removed in slit shape.
